(19) United States
(12) Patent Application Publication
(10) Pub. No.: US 2021/0080094 A1
(43) Pub. Date: Mar. 18, 2021

(54) LED LUMINAIRE DEVICE WITH ACTIVE COOLING SYSTEM USING PHASE CHANGING MATERIAL

(71) Applicant: SIGNIFY HOLDING B.V., Eindhoven (NL)

(72) Inventor: AJAY LAXMAN GOLE, PUNE (IN)

(21) Appl. No.: 17/024,011

(22) Filed: Sep. 17, 2020

Related U.S. Application Data
(60) Provisional application No. 62/901,448, filed on Sep. 17, 2019.

(51) Int. Cl. F21V 29/51; F21V 29/70; H05K 7/20

(52) U.S. Cl. CPC F21V 29/51; F21V 29/70; H05K 7/20318; F21Y 2115/10; H05K 7/20327; H05K 7/20381; H05K 7/2039

(57) ABSTRACT

Systems and methods for dissipating heat generated by a luminaire are disclosed. The system includes an adsorption region, a heat dissipation region, and a conduit in fluid communication with the adsorption region and the heat dissipation region. The adsorption region includes an adsorption chamber configured to hold an adsorbent and a coolant, and a cartridge heater placed within the adsorption chamber. The heat dissipation region is located proximate to one or more heat generation components of the luminaire. The conduit is configured to allows passage of the coolant from the adsorption chamber to the heat dissipation region for active cooling of the luminaire by absorption of heat by the coolant.

### PRIORITY

This application claims priority to U.S. Provisional Application No. 62/901,448, filed Sep. 17, 2019, the disclosure of which is incorporated herein by reference in its entirety.

### BACKGROUND

The advent of light emitting diode (LED) based luminaires has provided sports arenas, stadiums, other entertainment facilities, and other commercial and industrial facilities the ability to achieve instant on-off capabilities, intelligent controls and adjustability while delivering excellent light quality, consistent light output, color management, and improved energy efficiency. Because of this, users continue to seek improvements in LED luminaires. For example, new and improved ways to operate LED luminaires within a safe temperature range while reducing the overall size and weight of the LED luminaires are desired.

LED components in a luminaire and their drive electronics create a considerable amount of heat and increase in temperature above a safe threshold impacts the longevity life span and performance of a luminaire. Therefore, the generated heat must be dissipated to maintain optimum light output and maximize the luminaire's operating life. An increase in the luminaire temperature above a threshold also causes a decrease in the forward voltage and the lumen output of the LEDs. Operating a luminaire over its maximum rated temperature can also trigger a variety of stress mechanisms that considerably shorten the life of the LEDs. The higher temperatures also reduce the LED's color rendering index (CRI). The CRI is a technical measurement of how “true” the color is, based on an objective industry standard. Moreover, high power and high density luminaires (i.e., typically greater than 90 Watts) require large heatsinks, which are costly and mechanically impractical.

This document describes systems and methods that are directed to solving the issues described above, and/or other problems.

### SUMMARY

In certain scenarios, cooling systems and methods for dissipating heat generated by a luminaire are disclosed. The cooling system may include an adsorption region, a heat dissipation region, and a conduit in fluid communication with the adsorption region and the heat dissipation region. The adsorption region may include an adsorption chamber configured to hold an adsorbent and a coolant, and a cartridge heater placed within the adsorption chamber. The heat dissipation region may be located proximate to one or more heat generation components of the luminaire. The conduit may be configured to allows passage of the coolant from the adsorption chamber to the heat dissipation region for active cooling of the luminaire by absorption of heat by the coolant.

The cooling system may also include a condenser region disposed between the adsorption region and the heat dissipation region that is configured to reduce temperature of the coolant during passage of the coolant from the adsorption chamber to the heat dissipation region. Such reduction in the temperature of the coolant may cause the coolant to change phase from vapor to liquid. Optionally, the condenser region may be located adjacent to a heatsink included in the luminaire. Alternatively and/or additionally, the cooling system itself may include a heatsink located adjacent to the condenser region.

In various implementations, the cooling system may also include a coolant reservoir disposed between the condenser region and the heat dissipating region, the coolant reservoir configured to control the amount of coolant flowing through the heat dissipating region.

In certain scenarios, the coolant may be a phase change material (PCM) such as ammonia. The adsorbent may be activated carbon.

In various scenarios, the coolant may be adsorbed on the adsorbent in the adsorption chamber when a temperature of the luminaire is less than a threshold temperature. In some such scenarios, the coolant may be desorbed from the adsorbent in the adsorption chamber when a temperature of the luminaire is greater than or equal to a threshold temperature. Optionally, when the temperature of the luminaire is greater than or equal to the threshold temperature, the cartridge heater may be configured to heat the adsorbent to cause desorption of the coolant.

In certain implementations, the conduit of the cooling system may also include one or more valves to control the passage of the coolant between different regions of the cooling system.

The cooling system may either be completely included within a housing of the luminaire and/or only a portion of the cooling system (e.g., the heat dissipating region) may be included within a housing of the luminaire.

In some scenarios, a system for dissipating heat generated by a plurality of luminaires is disclosed. The system may include a plurality of luminaires comprising one or more light sources and a cooling system. The cooling system may include an adsorption region, a plurality of heat dissipation regions, and a plurality of conduits in fluid communication with the adsorption region and each of the plurality of the heat dissipation regions. The adsorption region may include an adsorption chamber configured to hold an adsorbent and a coolant, and a cartridge heater placed within the adsorption chamber. Each of the plurality of heat dissipating regions may be located inside each of the plurality of luminaires. Furthermore, each conduit may be configured to allow passage of the coolant from the adsorption chamber to a corresponding heat dissipation region for active cooling of the luminaire by absorption of heat by the coolant.

In various implementations, the system may also include a condenser region disposed between the adsorption region and the plurality of heat dissipation regions that is configured to reduce temperature of the coolant during passage of the coolant from the adsorption chamber to the plurality of heat dissipation regions.

In some implementations, the system may also include a processor and a non-transitory computer-readable medium comprising programming instructions. The processor may execute the programming instructions to cause the processor to receive temperature data from at least one of the plurality of luminaires, analyze the received temperature data to determine if temperature of a component of the at least one luminaire is greater than the threshold temperature, and control power delivered to the cartridge heater to cause desorption of the coolant from the adsorbent if the temperature of the component of the luminaire is greater than a threshold temperature. Optionally, the processor may also cause control of one or more valves of the cooling system such that the desorbed coolant flows through the heat dissipation region included in the at least one luminaire.

In some other scenarios, methods for dissipating heat generated by a luminaire may include receiving temperature data from the luminaire, analyzing the received temperature data to determine if temperature of a component of the luminaire is greater than a threshold temperature, and controlling power delivered to a cartridge heater of a cooling system to cause desorption of a coolant from an adsorbent to cause flow of the coolant through a heat dissipating region of the cooling system if the temperature of the component of the luminaire is greater than the threshold temperature. Optionally, flow of the coolant through the heat dissipating region of the cooling system causes decrease in temperature of the luminaire. The methods may also include controlling one or more valves of the cooling system such that the desorbed coolant flows through the heat dissipation region.

### BRIEF DESCRIPTION OF THE DRAWINGS

FIG. 1A illustrates a schematic side view of an example active cooling system within a housing of a luminaire.

FIG. 1B illustrates a schematic view of an example cooling system in fluid communication with a plurality of luminaires.

FIG. 2 illustrates a rear isometric view of a luminaire having the housing and active cooling system of FIG. 1.

FIG. 3 illustrates a block diagram of a coolant flow path through and around an example active cooling system.

FIG. 4A illustrates a block diagram of a coolant flow path through and around another example active cooling system.

FIGS. 4B and 4C illustrates different views of a schematic of an example cooling system of FIG. 4A.

FIG. 5 is a flowchart illustrating an example method for controlling the power supplied to an active cooling system based on the detection of temperature change, according to an embodiment.

FIG. 6 depicts an example of internal hardware that may be used to contain or implement the various processes and systems as described in this disclosure.

### DETAILED DESCRIPTION

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. As used in this document, the term “comprising” means “including, but not limited to.” When used in this document, the term “exemplary” is intended to mean “by way of example” and is not intended to indicate that a particular exemplary item is preferred or required.

In this document, when terms such as “first” and “second” are used to modify a noun, such use is simply intended to distinguish one item from another, and is not intended to require a sequential order unless specifically stated. The term “approximately,” when used in connection with a numeric value, is intended to include values that are close to, but not exactly, the number. For example, in some embodiments, the term “approximately” may include values that are within +/−10 percent of the value.

When used in this document, terms such as “top” and “bottom,” “upper” and “lower”, or “front” and “rear,” are not intended to have absolute orientations but are instead intended to describe relative positions of various components with respect to each other. For example, a first component may be an “upper” component and a second component may be a “lower” component when a device of which the components are a part is oriented in a first direction. The relative orientations of the components may be reversed, or the components may be on the same plane, if the orientation of the structure that contains the components is changed. The claims are intended to include all orientations of a device containing such components.

When used in this document, the terms “luminaire,” “lighting device,” “light fixture,” “lighting module” and “illumination device” are used interchangeably to refer to a device that includes a source of optical radiation. Sources of optical radiation may include, for example, light emitting diodes (LEDs), light bulbs, ultraviolet light or infrared sources, or other sources of optical radiation. In the embodiments disclosed in this document, the optical radiation emitted by the lighting devices includes visible light. A lighting device will also include a housing, one or more electrical components for conveying power from a power supply to the device's optical radiation source, and optionally control circuitry.

When used in this document, the terms “controller” and “controller device” mean an electronic device or system of devices containing a processor and configured to command or otherwise manage the operation of one or more other devices. A controller will typically include a processing device, and it will also include or have access to a memory device that contains programming instructions configured to cause the controller's processor to manage operation of the connected device or devices.

When used in this document, the terms “memory” and “memory device” each refer to a non-transitory device on which computer-readable data, programming instructions or both are stored. Except where specifically stated otherwise, the terms “memory” and “memory device” are intended to include single-device embodiments, embodiments in which multiple memory devices together or collectively store a set of data or instructions, as well as one or more individual sectors within such devices.

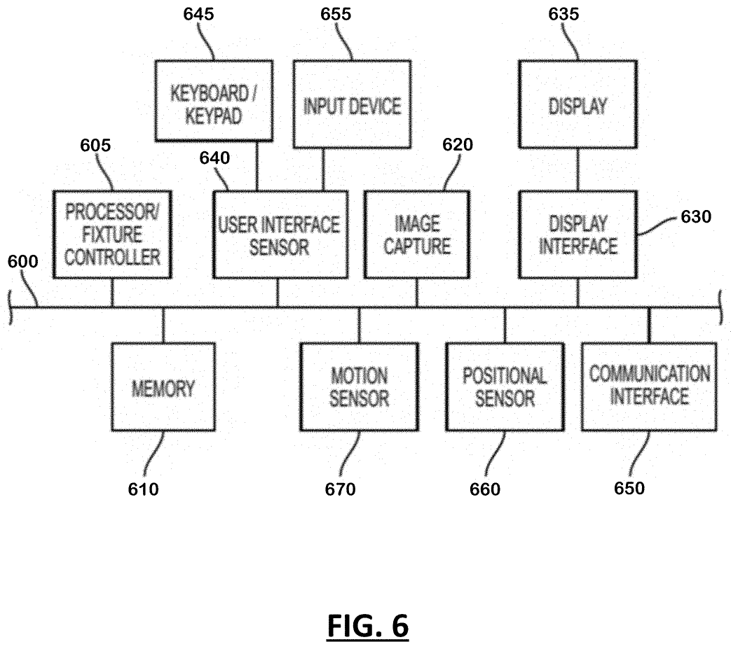

When used in this document, the terms “processor”, “processing device”, “processing circuit” refer to a hardware component of an electronic device (such as a controller) that is configured to execute programming instructions. Except where specifically stated otherwise, the singular term “processor” or “processing device” is intended to include both single processing device embodiments and embodiments in which multiple processing devices together or collectively perform a process. When used in this document, the term “electronic device” refers to an electronic device having a processor, a memory device, and a communication interface for communicating with proximate and/or local devices. The memory will contain or receive programming instructions that, when executed by the processor, will cause the electronic device to perform one or more operations according to the programming instructions. Additional elements that may be included in electronic devices will be discussed below in the context of FIG. 6.

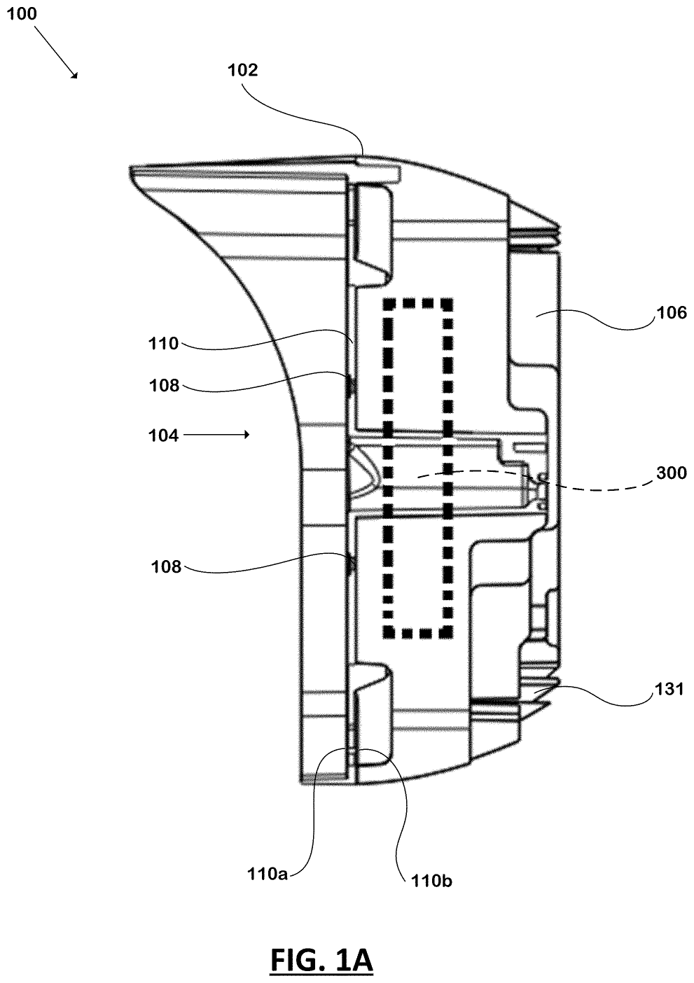

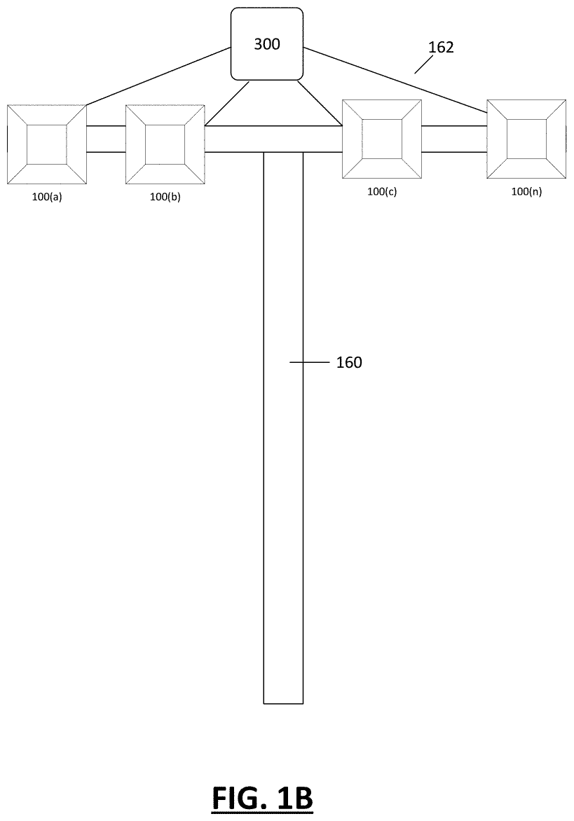

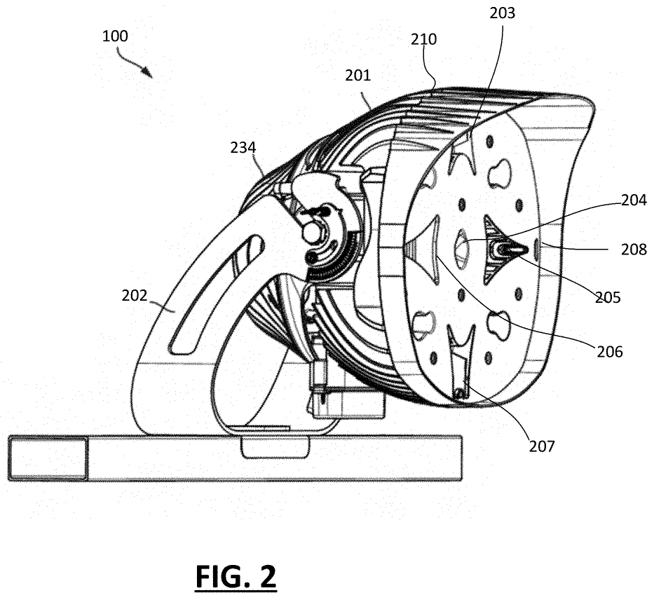

FIG. 1A illustrates a side view of an example active cooling system 300 enclosed within a luminaire 100, while FIG. 2 illustrates a rear isometric view of the luminaire 100.

The luminaire 100 may include a housing 102 having an opening 104 and one or more light sources 108 (such as LEDs). The light sources 108 may be mounted on a substrate 110, and may be sized and configured to direct through the opening 104. The substrate 110 may include an outer surface 110a and an inner surface 110b, such as the light sources 108 may be mounted on the front surface 110a and the active cooling system 300 positioned proximal to the inner surface 110b such that the heat dissipation region (discussed below) of the active cooling system 300 may absorb heat generated by the light sources 108. Optionally, the active cooling system 300 may be mechanically coupled to the substrate using any now or hereafter known attachment means. Since heat generated by the light sources 108 may increase the temperature within the housing 102, placement of the active cooling system 300 close to the light sources 108 may promote heat dissipation in a more efficient manner. However, other locations of the active cooling system 300 within the luminaire 100 are within the scope of this disclosure.

Optionally, the luminaire 110 may also include a passive cooling system such as the heatsink 106 for dissipating heat generated by the light sources 108. For example, the heat sink 106 may include any number of fins to increase its surface area that will contact a surrounding cooling medium (typically, air) to serve as a heat sink. In some embodiments, the heat sink 106 may be formed of aluminum and/or other metal, plastic or other suitable material. The position of the heat sink 106 and/or the fins on the mounting structure may depend on the type of light module 110 and its heat generation characteristics. In such embodiments, the active cooling system 300 may be placed inside the housing 102 between the substrate 110 and the heatsink 106, as shown in FIG. 1A. During operations, the heat generated from the light sources 108 which passes into the interior of the housing 102 may be dissipated by the active cooling system 300 and/or the heatsink 106 for heat dissipation.

In some embodiments, when the temperature of the luminaire 100 (and/or one or more of its components) increases above a threshold such that the heatsink 106 is unable to return the internal temperature of the housing 102 to within a safe operating temperature range, the active cooling system 300 may be operated (i.e., turned on) to dissipate the additional heat. Optionally, the active cooling system 300 may be operated in conjunction with the passive cooling by the heatsink 106 whenever the temperature of the luminaire (and/or one or more of its components) rises above a preset threshold. Therefore, heat generated in the luminaire 100 may be removed using the heatsink 106 and/or the active cooling system 300. This improves the life, functionality and performance of the luminaire 100. An advantage of the embodiments described herein is that the heatsink 106 may have a smaller footprint compared to a conventional luminaire that does not include an active cooling system 300, which in turn decreases the overall weight and cost of the improved luminaire 100.

The luminaire 100 has a base heat flux density when the active cooling system 300 is not operating and an increased heat flux density when the active cooling system 300 is operating. The heat flux density (e.g., heat flow rate intensity) is a flow of energy per unit of area per unit of time. In the International System of Units (SI), the heat flux density units are watts per square meter (W/m²). The heat flux density has both a direction and a magnitude, and so it is a vector quantity. Increase in the heat flux density by use of the active cooling system allows for miniaturization of components of the luminaire 100, such as the heatsink 106. The cooling methods of this disclosure provides better thermal performance of the luminaire 100. A benefit of an active cooling system 300 is that the heatsink 106 can be up to two-thirds smaller and lighter (and/or may even be operated without an additional heatsink) compared to the heatsink of a luminaire that is not cooled by the active cooling system. This reduces the cost of the heatsink 106, as well as the size and weight of the overall system. It also makes retrofitting luminaires 100 into new locations more viable. A reduction in the heatsink 106 size may also enhance performance by allowing operation of a luminaire 100 at higher power levels and/or a reduction in number of light sources 108 required to produce a similar illumination output.

One or more temperature sensors (not shown here) may also be included in the luminaire housing 102 to measure the temperature inside the housing 102 and/or temperature of various components of the luminaire 100. For example, a temperature sensor may be mounted on the substrate 110 and/or in the vicinity of the light sources 108 to measure heat generated by the light sources 108. Temperature data collected by the temperature sensor may be used to control the active cooling system 300 as described below.

An external power source may provide power (e.g., a battery) to the light source 108. During operation, various components of the luminaire 100 may generate heat such as, without limitation, the light sources 108 and the power supply. The active cooling system 300, when needed, may control the internal temperature of the luminaire 100 to within a safe operating temperature range by, for example, dissipating heat generated by the light source 108 and/or the power supply.

An example luminaire 100 is illustrated in FIG. 2. The luminaire 100 may include a light fixture 201 pivotably mounted on a mounting structure 202. The mounting structure 202 may be affixed to a support structure (e.g., a pole, ceiling, overhead rods, etc.) in a suitable configuration to provide a desired light output pattern from the light fixture 201 in a desired direction. The light fixture 201 may include a housing 210 and an optional power supply unit 234. In one or more embodiments, the housing 210 may encase various components of the light fixture. Specifically, the housing 210 may include an opening in which a set of optical radiation sources (e.g., LED modules 203-208) are secured to form a multi-module LED structure (e.g., front section). The LED modules may be positioned to emit light away from the light fixture 201. Each LED module may include one or more LEDs arranged in an array or other configuration. In various embodiments, the number of LEDs in each module may be any number that is sufficient to provide a high intensity LED device. Each LED module will also include a substrate on which the LEDs, various conductors and/or electronic devices, and/or optical elements (e.g., lenses) for the LEDs are mounted. In various embodiments, a light fixture may include multiple types of LED modules. For example, a lighting device may include a first type of LED module 203 having LEDs that are configured to selectably emit white light of various color temperatures, along with a second type of LED module 205 having LEDs that are configured to selectably emit light of various colors.

The housing 210 may also include an active cooling system 300 disposed proximal to the substrate that mounts the LEDs, to dissipate heat generated by the LEDs (as discussed below in more detail).

The housing 210 may include electrical components such as a luminaire controller, and wiring and circuitry to supply power and/or control signals to the LED modules. A luminaire controller may also be an external device to the luminaire 110. The luminaire controller may control drive currents supplied to the optical radiation sources of a luminaire and characteristics of light emitted by a luminaire. A luminaire controller may also control the operations of the active cooling system to provide heat dissipation from the luminaire.

The housing 210 may be also be connected to a power supply unit 234. The power supply unit 234 may include a battery, solar panel, or circuitry to receive power from an external and/or other internal source. The interior of the power supply unit 234 may include wiring or other conductive elements for the LED modules. In some embodiments, the power supply unit 234 may be attached to the housing 210 and/or included in the housing 210. Alternatively, the power supply unit 234 may be physically separated from the housing 210 and may be located, for example, at the base of the mounting structure 202. Other positions of the power supply unit 234 are within the scope of this disclosure.

While FIG. 1A shows that the active cooling system is included within the housing of a luminaire 100, the disclosure is not so limiting. The active cooling system 300 or a portion thereof may alternatively be located on the exterior of the housing 102 and/or at a location spaced from the housing 102. Optionally, a portion of the active cooling system may be situated outside the housing of the luminaire and may be in fluid communication with one or more luminaires, via one or more conduits. In such embodiments, the heat dissipation region (discussed below in more detail) is included within the housing of the luminaire(s), while the other components of the active cooling system (e.g., the condenser region and the adsorption region) are located outside the luminaire and are in fluid communication with the heat dissipation region. For example, as shown in FIG. 1B the active cooling system 300 is in fluid communication with luminaires 100a, 100b, 100c, . . . 100n mounted on a support structure 160, via conduits 162. In such embodiments, the housing of a luminaire may include the heat dissipation region disposed proximate to the substrate that mounts the light sources (and/or other heat generating sections of the housing) in order to facilitate collection/absorption of heat generated by the LEDs or otherwise within the luminaire housing by the coolant flowing through the heat dissipation region (e.g., the heat dissipation region including a bundle of parallel lines disposed close to the substrate on which the light sources are mounted). The heat dissipation region is in fluid communication with the other components of the active cooling system 300 via conduits 162.

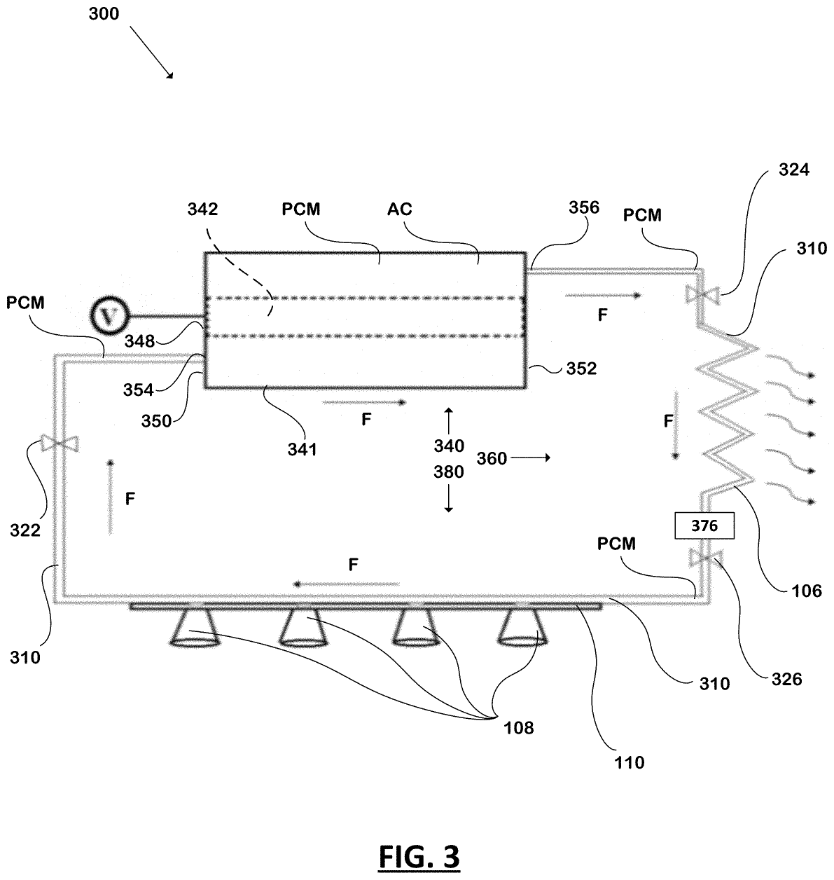

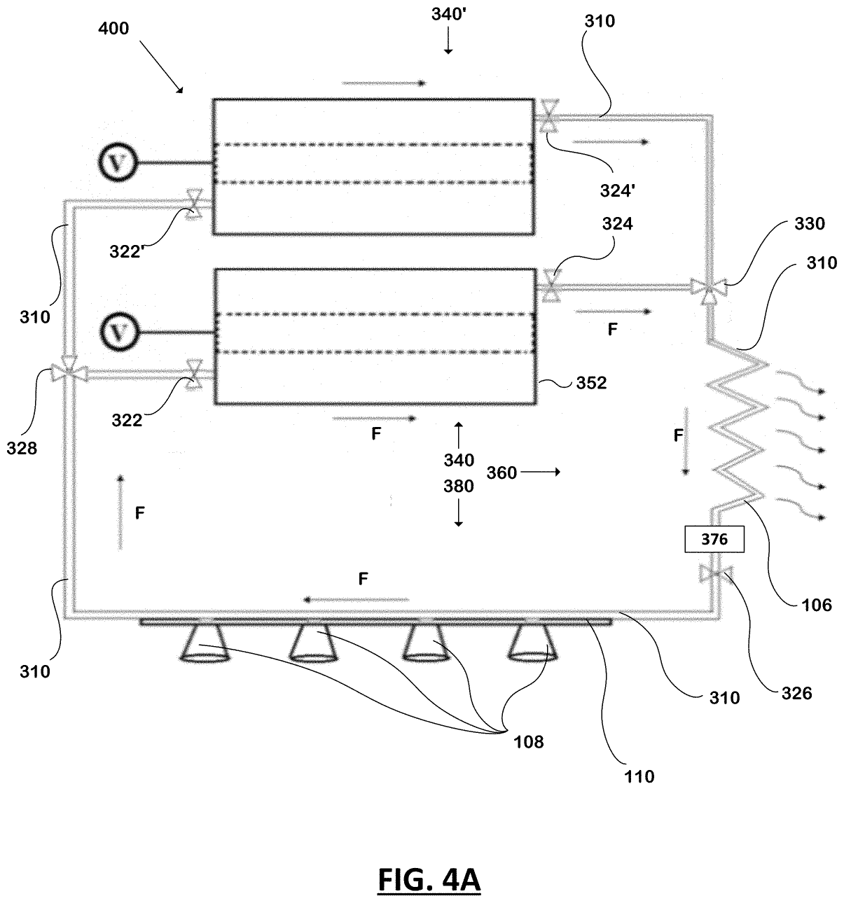

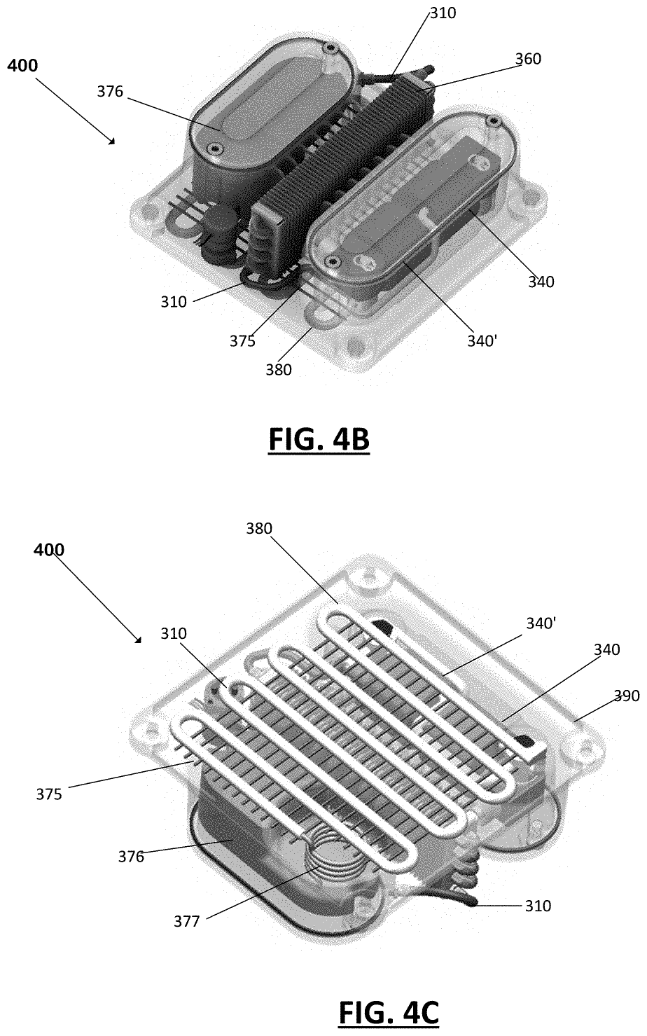

The active cooling system 300 will now be described using FIGS. 3, 4A, 4B, and 4C. FIG. 3A illustrates a block diagram of an example single-module active cooling system 300 and a coolant flow path F between various components of the active cooling system 300. FIG. 4 illustrates a block diagram of an example a multi-module active cooling system 400 and a coolant flow path F within between various components of the active cooling system. FIGS. 4A and 4B illustrate front and back perspective schematic views of an example active cooling system FIG. 4 (including two modules).

Referring now to FIG. 3, the active cooling system 300 may include various regions, such as, for example, an adsorption region 340, a condenser region 360, and a heat dissipation region 380 in fluid communication with each other via a continuous conduit (e.g., piping and channels) 310. The conduit 310 may be configured to allow passage of a coolant between the regions, and may include one or more valves 322, 324 and 326 to control the flow of the coolant. For example, the conduit 310 may be individual pipes interconnecting the components of regions 340, 360, and 380 of the active cooling system 300.

In certain embodiments, portions of the conduit 310 (in particular the conduit within the heat dissipation region 380) may be directed to and/or located in various locations within the housing of a luminaire. For example, in the implementation of FIG. 1B, the portions of the conduit within the heat dissipation region are included within the luminaire housing and other portions of the active cooling system are outside the luminaire housing. Alternatively, the components of regions 340, 360, and 380 may be collected within a unitary body of the active cooling system (e.g., as shown in FIG. 1A) having interior channels to provide the coolant flow path F between the components of regions 340, 360, and 380 of the unitary body.

The adsorption region 340 may include an adsorption chamber 341 comprising an internal volume that is configured to hold an adsorption component (AC) and a coolant adsorbed on the AC. The AC is a solid material that adsorbs the coolant on its surface. Examples of the AC include, without limitation, activated carbon, silica gel, zeolite, charcoal, or the like. The coolant may be a phase change material (PCM) that is adsorbed on the surface of the AC under optimal temperature and pressure conditions in liquid phase or vapor phase. Examples of the coolant may include, without limitation, ammonia, ethanol, methanol, water, or the like.

Sorption is a surface adhesion phenomenon and occurs when atoms, ions or molecules from one substance becomes attached to another substance (which is a solid). The adsorbate is the substance that is to be adsorbed and the adsorbent is the reactant substance that adsorbs the adsorbate. The adsorbate may be in a gas, liquid or dissolved solid state. There are three common forms of sorption: adsorption occurs when the adsorbate attaches to the surface of the adsorbent; absorption occurs when the adsorbate attaches within the surface of the adsorbent; and ion exchange occurs when ions from the adsorbate exchange with ions from the adsorbent, but the substances do not mix. Desorption is the reverse of sorption. The phenomenon may be used for changing the temperature of a material (i.e., cooling or heating) by changing the phase of the material.

Referring back to FIG. 3, the adsorption chamber 341 may also include a cartridge heater 342 (e.g. liquid immersion heater), a conduit inlet 354 on a first end 350, and a conduit outlet 356 on a second end 352. A first valve 322 may control the flow of coolant through the conduit inlet 354 and a second valve 324 may control the flow of coolant through the conduit outlet 356. The first valve 322 and second valve 324 may be one-way valves (e.g., non-return valves or check valves) permitting liquids and gases (e.g., fluids) to flow in one direction only. For example, the first valve 322 may permit the flow of coolant to the adsorption chamber 341 and the second valve 324 may permit the flow of coolant from the adsorption chamber 341. The first valve 322 and second valve 324 may also be pressure changing valves, for example capillary valves.

In certain embodiments, the adsorption chamber 341 may be an annular tube or cylindrical chamber that may receive a cartridge heater 342. The cartridge heater 342 may receive electrical power V from an external power source, and may use the power to increase the temperature of the AC included in the adsorption chamber 341. In certain embodiments, increase in temperature of the AC leads to desorption of the coolant from the surface of the AC, and the desorbed coolant may exit the adsorption chamber via the outlet 356. While FIG. 3 shows one cartridge heater, multiple cartridge heaters 342 may be included within the adsorption chamber 341.

In various implementations, the cartridge heater 342 may be turned on when the cooling system 300 needs to be operated for dissipating heat from one or more luminaires. Specifically, when the cartridge heater 342 is turned off, the coolant is adsorbed on the AC, and does not flow through the conduit 310 to dissipate heat from the luminaire. As such, during operation of the active cooling system 300, the cartridge heater 342 may remain turned on until the pressure and/or temperature within the condenser region 360 reaches the desired pressure and/or temperature that allows a certain amount of desorbed coolant to exit the adsorption chamber. The amount of coolant (and the relational pressure/temperature) may be determined based on, for example, the measured temperature of the luminaire/luminaire components, the desired cooling efficiency, the desired temperature of the luminaire/luminaire components, or the like. Alternatively, the cartridge heater may be turned on and/or for a certain time periods while the light sources are turned on, and/or while the temperature of the components of the housing is determined to be above a threshold temperature.

Upon exiting the adsorption chamber, the coolant is passed through a condenser region 360 in the flow path F. The condenser region 360 may be a heat discharge region or cooling region of the active cooling system 300 in which the coolant is condensed (for e.g., vaporized coolant from the adsorption chamber is turned into liquid coolant by cooling). The condenser region may utilize any, now or hereafter known, condenser systems and methods. Optionally, condenser may be positioned proximate to a heatsink (a secondary heatsink 375—shown in FIGS. 4B and 4C) of the active cooling system 300 and/or a heatsink of the luminaire (e.g., when the active cooling system is enclosed within the luminaire housing) such that when the coolant flows through the condenser region 360, the heatsink may aid in absorption of heat from the coolant. The cooler coolant may continue to the heat dissipation region 380 of the active cooling system 300 to absorb heat generated inside a luminaire. Cooling of the coolant in the condenser region 360 may increase the heat absorption and capacity of the coolant, and may also aid in changing the phase of the coolant (e.g., from vapor phase to liquid phase).

The heat dissipation region 380 is a heat intake region of the active cooling system 300, and may include a portion of the conduit 310 adjacent to and/or proximate to heat generating regions of the luminaire 100 such as the substrate 110 on which the heat generating light sources 108 are mounted (as shown in FIG. 3), the power supply, or the like. In one or more embodiments, a coolant flowing through the conduit 310 in the heat dissipation region 380 may absorb heat generated in the luminaire 100 (via the surface of the conduit) to bring the internal temperature of the luminaire within an acceptable operational range. As such, the material of the conduit in the heat dissipation region may be selected to allow for optimal/desired heat transfer from the luminaire to the coolant in the conduit. Optionally, the surface area of the conduit in the heat dissipation region (and/or the volume of the coolant in the heat dissipation region) may be increased by, for example, providing a bundle of one or more parallel (or other configuration) channels or pipes that together form the conduit in the heat dissipation region (as shown in FIG. 4C). In other embodiments, heat transfer between the luminaire and the coolant liquid may also be increased by incorporating fins and/or other elements with a large surface area in the surface of the conduit 310 within the heat dissipation region 380, and these elements with a large surface area in turn transfer heat to the inner surface of the conduit.

As the temperature of the coolant within the conduit 310 adjacent the heat dissipation region 380 increases, it flows through the first valve 322 back to the condenser region 360 (where the coolant may again be cooled), via the adsorption chamber 341 that is maintained at a suitable pressure and/or temperature (to prevent adsorption of the coolant on the AC). Therefore, a continuous flow of coolant is maintained in the heat dissipation region 380 until the temperature of the luminaire remains above a threshold value. In certain embodiments, if the coolant is re-adsorbed by the AC before adequate heat dissipation (e.g., pressure and temperature within the adsorption chamber 341 reach adsorption values), the cartridge heater 342 may be turned back on to activate desorption of the coolant. Optionally, this will continue until a temperature sensor (disposed within the luminaire) determines a desired temperature within the luminaire has been reached. Upon such determination, power to the cartridge heater 342 is turned off such that the AC may adsorb the coolant again, and the active cooling is stopped.

In certain embodiments, a valve 326 may control the flow of coolant to the heat dissipation region 380 from the condenser region. The third valve 326 may be a one-way valve (e.g., non-return valves or check valves) permitting liquids and gases (e.g., fluids) to flow in one direction only—from the condenser region 360 to the heat dissipation region 380. The third valve 326 may also be pressure changing valve, for example capillary valves or throttle valves.

In certain implementations, a coolant reservoir 376 may be disposed between the condenser region 360 and the heat dissipation region 380 for storing liquid coolant received from the condenser region 360 before it is transferred to the conduit in the heat dissipation region 380. Such intermediate storage of the coolant allows for finer control of the coolant flowing through the conduit in the heat dissipation region based on, for example, the amount of heat generated in the luminaire adjacent the heat generation region 380. For example, the amount of coolant transferred to the conduit in the heat dissipation region 380 may be directly proportional to the heat generated in the luminaire. The amount of coolant drawn from the reservoir may be controlled using for example, a valve (e.g., a capillary valve 377 shown in FIG. 4C—other types of valves such as expansion valves are within the scope of this disclosure) that is controlled based on the temperature of the luminaire.

As discussed above, the condenser region 360 may include an increased area of piping in the conduit 310 adjacent the heatsink 106. Likewise, the heat dissipation region 380 may include an increased area of piping in the conduit 310 adjacent the substrate 110. The increased area of piping in both the condenser 360 and the heat generator 380 provides for greater heat transfer across a large surface area.

In certain embodiments, the AC may include activated carbon and the coolant may include ammonia (NH₃) as a PCM. Activated carbon is a form of carbon (e.g., charcoal) that has been heated or otherwise treated to increase it's the surface area available for adsorption. In such embodiments, the pressure within the adsorption chamber 341 may be about 0.5 bar to about 3.5 bar, about 1 bar to about 3 bar, about 1.5 bar to about 2.5 bar, or about 2 bar. The pressure within the conduit 310 in the condenser region 360 may be about 15 bar to about 25 bar, about 17 bar to 23 bar, about 19 bar to about 21 bar, or about 20 bar. The pressure within the conduit 310 in the heat dissipation region 380 may be about 0.5 bar to about 3.5 bar, about 1 bar to about 3 bar, about 1.5 bar to about 2.5 bar, or about 2 bar. Other pressure ranges are within the scope of this disclosure. The approximate boiling temperature (e.g., boiling point) of ammonia at 2 bar is about −20° C. and at 20 bar is about 50° C.

When the active cooling system 300 is not operating and temperature of the adsorption chamber 341 is equivalent to the outside ambient temperature, ammonia is adsorbed on the activated charcoal (pressure of 2 bar). The optimal temperature range of ammonia PCM for adsorption to occur is −20° C. to 70° C. When the outside ambient temperature is above approximately −20° C., ammonia may be adsorbed in a vapor state, and when the outside ambient temperature is below approximately −20° C., the ammonia may be adsorbed in a liquid state.

The active cooling system 300 may be turned on (for e.g., in response to determining that the temperature of the luminaire(s) is above a threshold) by powering the cartridge heater 342 to increase the temperature within the adsorption chamber 341. The pressure within the adsorption chamber 341 may increase with the addition of heat from the cartridge heater 342 until a desired temperature and/or pressure is reached after which the cartridge heater 342 is turned off. Upon heating, the adsorption capacity of the activated charcoal AC decreases thereby allowing the ammonia vapor PCM to be released from the surfaces of the activated charcoal AC. The desorbed ammonia vapor PCM may exit the adsorption chamber 341 through the outlet 356 and may pass through the second valve 324 to the condenser region 360.

Conversely, when the active cooling system 300 is not required to cool the interior of the luminaire 100, the cartridge heater 342 may be powered off such that the adsorption capacity of the activated carbon AC increases (i.e., is re-inverted) thereby allowing the ammonia PCM to be re-adsorbed on the surface of the activated carbon AC as it cools.

As discussed above, the pressure within the conduit 310 in the condenser region 360 is approximately 20 bar and, therefore, the boiling point is about 50° C. As heat is removed from the ammonia vapor PCM in the condenser region 360 by the heatsink 106, the temperature of the ammonia PCM decreases to a temperature below the boiling point, wherein a phase change occurs such that the ammonia vapor PCM is converted to ammonia liquid PCM. The cooler liquid ammonia pass through the third valve 326, which includes a capillary valve to reduce the pressure and continues to the heat dissipation region 380 in order to absorb heat from the luminaire 100.

As discussed above with respect to FIG. 1A, an optional temperature sensor may be positioned adjacent to the heat generating regions of the luminaire (e.g., in the vicinity of the light sources, near a power supply, etc.). An example temperature sensor may be a thermocouple including two dissimilar wires (e.g., electrical conductors) that connect (e.g., forming an electrical junction) after a certain temperature (e.g., a threshold) is reached, and may send a voltage signal to a processor and/or controller (located within and/or outside the luminaire) which may in turn power on the active cooling system 300 (as described in more detail below). For example, once the temperature sensor determines (e.g., detects or measures) that the temperature of the interior of the luminaire has reached a threshold (e.g., about 65-85° C., 70-80° C., about 72-78° C., about 75° C. at atmospheric pressure), the controller may cause power V to be supplied to the cartridge heater 342 to begin the active cooling process. One or more temperature sensors may be used in the luminaire. For example, multiple temperature sensors may be positioned on the substrate adjacent each light source, or one or more temperature sensors may be positioned adjacent to various heat generating components of the luminaire. In certain embodiments, the active cooling system 300 may continue to cool the interior of the luminaire 100 until a lower temperature threshold is detected by the temperature sensor, and the controller may then cause deactivation of the active cooling system 300 to a dormant state (i.e., discontinuing the supply of power V to the active cooling system 300).

Alternatively and/or additionally, the active cooling system 300 may automatically be activated after a certain time period of activity of the luminaire 100, the power supply of the luminaire 100, and/or light sources 108 included in the luminaire 100. Similarly, the active cooling system 300 may automatically be deactivated after a certain time period of inactivity of the luminaire 100, the power supply of the luminaire 100, and/or light sources 108 included in the luminaire 100. In certain other embodiments, the active cooling system 300 may be activated or deactivated upon receipt of user instructions, either by manual input or by wireless signal.

Active cooling systems 300 as described above are ideal for chip-on-board (COB) LEDs, comprising multiple LEDs mounted on one printed circuit (PC) board (e.g. substrate 110). LEDs used in a COB arrangement are chips that are not traditionally packaged. As a result, the LEDs can be packaged to take up less space and provide greater accessibility. When used with a COB device, an active cooling system 300 of this disclosure can effectively lower the heat temperature to about 90° F./36° C., well below the 120° C. operating threshold of typical COB devices.

FIG. 4A illustrates a block diagram of an example multi-module active cooling system 400 and a coolant flow path F. The two-module active cooling system 400 is similar to the single-module active cooling system 300, and like parts will not be further discussed. The multi-module active cooling system 400 may include a plurality of adsorption regions (instead of a single adsorption region in the embodiment shown in FIG. 3). For example, as shown in FIG. 4A, the multi-module active cooling system 400 may include two adsorption regions 340, 340′. Coolant flowing through the conduit 310 from the heat dissipation region 380 may be directed to one or more of the plurality of adsorption regions 340 340′ by controlling the first three way valve 328 and the second three way valve 330. Specifically, the first adsorption region 340 and the second adsorption region 340′ may operate in alternating desorbing and adsorbing modes, via opening and/or closing of the first three way valve 328 and the second three way valve 330. Each adsorption region may optionally include an inlet throttle valve (first valves 322, 322′) and an outlet throttle valve (second valves 324, 324′) to ensure pressurized coolant does not enter the incorrect flow path.

For example, in a first cycle the first adsorption region 340 may operate in a desorbing mode and the second adsorption region 340′ may operate in an adsorbing mode, by maintaining suitable pressure and temperature to promote desorption in the first adsorption region 340 and adsorption in the second adsorption region 340′. As such in the first cycle, coolant may be desorbed in first adsorption region 340, flow through valve 324 and valve 330 (prevents back flow to the first adsorption region 340 and the second adsorption region 340′) to the condenser region 360, and then to the heat dissipation region 380 (via the valve 326). After absorption of heat generated in the luminaire at the heat generation region 380, the coolant may be directed by the three-way valve 328 into the second adsorption region 340′ for adsorption instead of into the first adsorption region 340.

In a second cycle, the first adsorption region 340 may operate in an adsorbing mode and the second adsorption region 340′ may operate in a desorbing mode, by maintaining suitable pressure and temperature to promote adsorption in the first adsorption region 340 and desorption in the second adsorption region 340′. As such in the second cycle, coolant may be desorbed in second adsorption region 340′, flow through valve 324′ and valve 330 (prevents back flow to the first adsorption region 340 and the second adsorption region 340′) to the condenser region 360, and then to the heat dissipation region 380 (via the valve 326). After absorption of heat generated in the luminaire 100 at the heat generation region 380, the coolant may be directed by the three-way valve 328 into the first adsorption region 340 for adsorption instead of into the second adsorption region 340′.

The first and second cycle may be executed alternatively for a defined period of time until a desired temperature is achieved in the corresponding luminaire(s). There may be multiple cycles of adsorption and desorption occurring during the active cooling process. The time period for each cycle may be predetermined to optimally allow for almost complete desorption and/or adsorption of the coolant in the respective adsorption chambers. The first three way valve 328 and second three way valve 330 may be directional control valves controlled by a processor or a controller configured to control operation of the active cooling system 400 in alternating cycles, as described above. Use of two or more adsorption regions may increase the efficiency of the active cooling system (i.e., cool down the luminaire in lesser time) and/or may lead to less power consumption by the active cooling system

FIGS. 4B and 4C illustrate various views of a schematic illustration of the example active cooling system of FIG. 4A. As shown in the FIGS. 4B and 4C, the various components of the active cooling system 400 may be mounted on either side of a support structure 390. For example, the secondary heat sink 375 and the conduit 310 portion in the heat dissipating region 380 may be mounted on one side of the support structure 390, and the remaining components may be mounted on the opposite side of the support structure 390. However, the disclosure is not so limiting and the sides on which the components are mounted are configurable based on various practical considerations. Optionally, the support structure 390 may include attachment means to various components of a luminaire (e.g., a substrate, housing, heatsink, etc.) such that the heat dissipating region 380 is in close proximity of the heat generating component(s) of the luminaire.

Optionally, the active cooling system 300 may include one or more antennae, transceivers or other communication devices (not shown here) that can receive control signals from an external source, control signals from the luminaire(s), data from a temperature sensor(s) included within the luminaire(s) housing, or the like. For example, the active cooling system 300 may include a wireless receiver and an antenna that is configured to receive control signals via a wireless communication protocol.

Various components and/or operations of the active cooling system 300 (e.g., valves, power supply to the heater cartridge, etc.) may be controlled by a processor or a controller. Such a processor or controller may be included in a luminaire, the active cooling system, and/or an external device. Such processor may provide suitable instructions to the active cooling system using any known communication protocol and methods (e.g., wirelessly or wired, Bluetooth, I2C, NFC, or the like). Alternatively and/or additionally, a user may manually control the operation of the active cooling system.

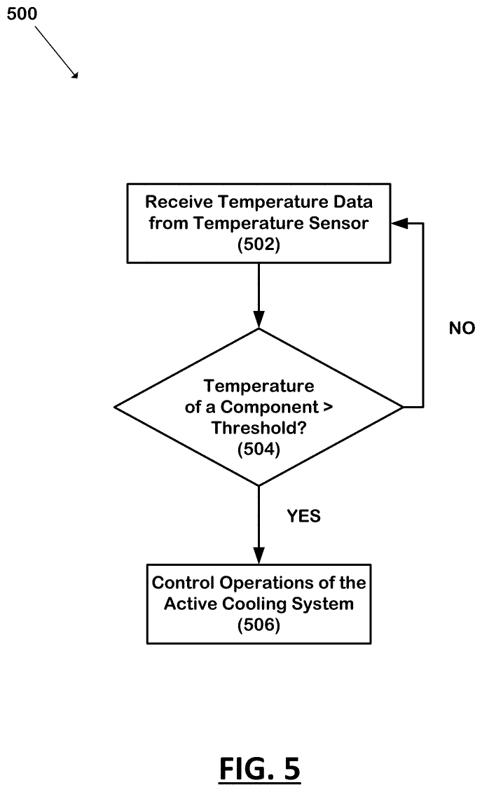

FIG. 5 illustrates an example flowchart in accordance with various embodiments illustrating and describing a method 500 of monitoring the internal temperature of a luminaire and controlling an active cooling system to manage the internal temperature of the luminaire of FIG. 1. While the method 500 is described for the sake of convenience and not with an intent of limiting the disclosure as comprising a series and/or a number of steps, it is to be understood that the process does not need to be performed as a series of steps and/or the steps do not need to be performed in the order shown and described with respect to FIG. 5 but the process may be integrated and/or one or more steps may be performed together, simultaneously, or the steps may be performed in the order disclosed or in an alternate order.

At 502, a controller may receive temperature data from one or more temperature sensor(s) (e.g., a temperature sensor) included in a luminaire. The controller may analyze (504) the temperature data to determine if the inside temperature and/or temperature of one or more components of the luminaire is higher than a threshold temperature. The controller may determine the threshold temperature by accessing a rule set that includes threshold temperatures for various parameters such as ambient conditions, material of manufacture of various components, type of LEDs, use of LEDs, heatsink characteristics, presence and/or absence of a heatsink, power being delivered to the LEDs, expected runtime of the luminaire, current properties of the luminaire/components, etc. (as discussed above). For example, if the optical elements of the luminaire are made from silicone that degrades at about 110° C., the threshold temperature may be determined to keep the inside temperature of the luminaire below 110° C. (e.g., 105° C.). In certain embodiments, the threshold temperature may be adjusted based the outside temperature or other ambient conditions. As another example, the threshold temperature may be lower in the presence of dirt or debris on the lighting module compared to when dirt or debris is not present in order to reduce overheating of the lighting module in a short period of time.

If the inside temperature and/or temperature of one or more components of the luminaire is determined to be higher than the threshold temperature, the controller may control operations of the active cooling system (506) to bring the temperature of the luminaire within a desirable range. For example, the controller may selectively supply power to one or more cartridge heaters in an active cooling system of the luminaire to initiate flow of coolant in the heat dissipation region of the active cooling system for dissipating heat from the luminaire. Optionally, the controller may also be configured to control opening and/or closing of one or more valves of the active cooling system to promote and/or facilitate flow of the coolant in the active cooling system. For example, the controller may control a valve at the outlet of a coolant reservoir disposed between the condenser region and the heat dissipating region of the active cooling system such that an optimal amount of coolant flows through the conduit in the heat dissipating region.

In certain embodiments, the controller may also reduce the power supplied to one or more LEDs while maintaining an output of the luminaire at a substantially constant level by, for example, turning on other LEDs and/or other luminaires, increasing power to other LEDs, or increasing PWM for other LEDs and/or luminaires.

As such, controlling the power supplied to cartridge heaters of the active cooling system dependent upon an internal temperature of the luminaire can extend the useful life of the luminaire. For example, the useful life can be extended by limiting the possibility for heat related damage by preventing the temperature to rise above a threshold temperature sufficient to cause damage to the internal components and/or lens of the luminaire.

In certain embodiments, the controller may turn off power supplied to the cartridge heaters if the temperature of the inside of the luminaire is determined to be below a second threshold level, upon receipt of user instruction, or after a certain time period (e.g., time period sufficient to allow cooling of the luminaire).

FIG. 6 is a block diagram of hardware that may be including in any of the electronic devices described above, such as a luminaire or controller device. A bus 600 serves as an information highway interconnecting the other illustrated components of the hardware. The bus may be a physical connection between elements of the system, or a wired or wireless communication system via which various elements of the system share data. Processor 605 is a processing device of the system performing calculations and logic operations required to execute a program. Processor 605, alone or in conjunction with one or more of the other elements disclosed in FIG. 6, is an example of a processing device, computing device or processor as such terms are used within this disclosure. The processing device 605 may be a physical processing device, a virtual device contained within another processing device, or a container included within a processing device. If the electronic device is a lighting device (e.g., a LED luminaire), processor 605 may be a component of a fixture controller, and the device would also include a power supply and optical radiation source as discussed above.

A memory device 610 is a hardware element or segment of a hardware element on which programming instructions, data, or both may be stored. An optional display interface 630 may permit information to be displayed on the display 635 in audio, visual, graphic or alphanumeric format. Communication with external devices, such as a printing device, may occur using various communication interfaces 650, such as a communication port, antenna, or near-field or short-range transceiver. A communication interface 650 may be communicatively connected to a communication network, such as the Internet or an intranet.

The hardware may also include a user input interface 640 which allows for receipt of data from input devices such as a keyboard or keypad 645, or other input device 655 such as a mouse, a touchpad, a touch screen, a remote control, a pointing device, a video input device and/or a microphone. Data also may be received from an image capturing device 620 such as a digital camera or video camera. A positional sensor 660 and/or motion sensor 670 may be included to detect position and movement of the device. Examples of positional sensors 660 such as a global positioning system (GPS) sensor device that receives positional data from an external GPS network. Examples of motion sensors 670 may include gyroscopes or accelerometers.

The above-disclosed features and functions, as well as alternatives, may be combined into many other different systems or applications. Various presently unforeseen or unanticipated alternatives, modifications, variations or improvements may be made by those skilled in the art, each of which is also intended to be encompassed by the disclosed embodiments.

1. A cooling system for dissipating heat generated by a luminaire, the cooling system comprising:
an adsorption region comprising:
an adsorption chamber configured to hold an adsorbent and a coolant, and
a cartridge heater placed within the adsorption chamber;
a heat dissipation region, wherein the heat dissipation region is located proximate to one or more heat generation components of the luminaire; and
a conduit in fluid communication with the adsorption region and the heat dissipation region, wherein the conduit allows passage of the coolant from the adsorption chamber to the heat dissipation region for active cooling of the luminaire by absorption of heat by the coolant.

2. The cooling system of claim 1, further comprising a condenser region disposed between the adsorption region and the heat dissipation region, the condenser region configured to reduce temperature of the coolant during passage of the coolant from the adsorption chamber to the heat dissipation region.

3. The cooling system of claim 2, wherein the condenser region is located adjacent to a heatsink included in the luminaire.

4. The cooling system of claim 2, further comprising a heatsink located adjacent to the condenser region.

5. The cooling system of claim 2, wherein reduction in the temperature of the coolant causes the coolant change phase from a vapor phase to a liquid phase.

6. The cooling system of claim 2, further comprising a coolant reservoir disposed between the condenser region and the heat dissipating region, the coolant reservoir configured to control the amount of coolant flowing through the heat dissipating region.

7. The cooling system of claim 1, wherein the coolant is a phase change material (PCM).

8. The cooling system of claim 1, wherein the coolant is adsorbed on the adsorbent in the adsorption chamber when a temperature of the luminaire is less than a threshold temperature.

9. The cooling system of claim 1, wherein the coolant is desorbed from the adsorbent in the adsorption chamber when a temperature of the luminaire is greater than or equal to a threshold temperature.

10. The cooling system of claim 9, wherein when the temperature of the luminaire is greater than or equal to the threshold temperature, the cartridge heater is configured to heat the adsorbent to cause desorption of the coolant.

11. The luminaire of claim 1, wherein:
the adsorbent is activated carbon, and
the coolant is ammonia.

12. The luminaire of claim 1, wherein the conduit comprises one or more valves to control the passage of the coolant between different regions of the cooling system.

13. The cooling system of claim 1, wherein the cooling system is included within a housing of the luminaire.

14. The cooling system of claim 1, wherein the heat dissipating region is included within a housing of the luminaire.

15. A system for dissipating heat generated by a plurality of luminaires, the cooling system comprising:
a plurality of luminaires comprising one or more light sources; and
a cooling system comprising:
an adsorption region comprising:
an adsorption chamber configured to hold an adsorbent and a coolant, and
a cartridge heater placed within the adsorption chamber,
a plurality of heat dissipation regions, each of the plurality of heat dissipating regions located inside each of the plurality of luminaires, and
a plurality of conduits in fluid communication with the adsorption region and each of the plurality of the heat dissipation regions, wherein each conduit allows passage of the coolant from the adsorption chamber to a corresponding heat dissipation region for active cooling of the luminaire by absorption of heat by the coolant.

16. The system of claim 15, further comprising a condenser region disposed between the adsorption region and the plurality of heat dissipation regions, the condenser region configured to reduce temperature of the coolant during passage of the coolant from the adsorption chamber to the plurality of heat dissipation regions.

17. The system of claim 15, further comprising:
a processor; and
a non-transitory computer-readable medium comprising programming instructions that when executed cause the processor to:
receive temperature data from at least one of the plurality of luminaires,
analyze the received temperature data to determine if temperature of a component of the at least one luminaire is greater than the threshold temperature, and
in response to determining that the temperature of the component of the luminaire is greater than a threshold temperature, control power delivered to the cartridge heater to cause desorption of the coolant from the adsorbent.

18. The system of claim 17, further comprising programming instructions that when executed cause control of one or more valves of the cooling system such that the desorbed coolant flows through the heat dissipation region included in the at least one luminaire.

19. A method for dissipating heat generated by a luminaire, the method comprising, by a processor:
receiving temperature data from the luminaire;
analyzing the received temperature data to determine if temperature of a component of the luminaire is greater than a threshold temperature, and
in response to determining that the temperature of the component of the luminaire is greater than the threshold temperature, controlling power delivered to a cartridge heater of a cooling system to cause desorption of a coolant from an adsorbent to cause flow of the coolant through a heat dissipating region of the cooling system,
wherein flow of the coolant through the heat dissipating region of the cooling system causes decrease in temperature of the luminaire.

20. The method of claim 19, further comprising controlling one or more valves of the cooling system such that the desorbed coolant flows through the heat dissipation region.
